(19) United States
(12) Patent Application Publication
(10) Pub. No.: US 2026/0122901 A1
(43) Pub. Date: Apr. 30, 2026

(54) VERTICAL NAND FLASH MEMORY DEVICE, METHOD OF FABRICATING THE VERTICAL NAND FLASH MEMORY DEVICE, AND ELECTRONIC APPARATUS INCLUDING THE VERTICAL NAND FLASH MEMORY DEVICE

(71) Applicant: Samsung Electronics Co., Ltd., Suwon-si (KR)

(72) Inventors: Hoseok HEO, Suwon-si (KR); Minhyun LEE, Suwon-si (KR); Seungdam HYUN, Suwon-si (KR)

(73) Assignee: Samsung Electronics Co., Ltd., Suwon-si (KR)

(21) Appl. No.: 19/369,908

(22) Filed: Oct. 27, 2025

(30) Foreign Application Priority Data
Oct. 29, 2024 (KR) 10-2024-0149930

(51) Int. Cl. H10B 43/35; H10B 43/27

(52) U.S. Cl. CPC H10B 43/35; H10B 43/27

(57) ABSTRACT

Provided are a vertical NAND flash memory device, a method of fabricating the vertical NAND flash memory device, and an electronic apparatus including the vertical NAND flash memory device. The vertical NAND flash memory device includes a plurality of cell strings each extending in a direction perpendicular to a substrate. Each of the plurality of cell strings includes a channel layer, a charge trap layer provided on the channel layer and including an amorphous oxide, at least one insertion layer provided inside the charge trap layer, and a plurality of gate electrodes provided on the charge trap layer.

### CROSS-REFERENCE TO RELATED APPLICATION

This application is based on and claims priority under 35 U.S.C. § 119 to Korean Patent Application No. 10-2024-0149930, filed on Oct. 29, 2024, in the Korean Intellectual Property Office, the disclosure of which is incorporated by reference herein in its entirety.

### BACKGROUND

Some example embodiments relate to a vertical NAND flash memory device, a method of fabricating the vertical NAND flash memory device, and/or an electronic apparatus including the vertical NAND flash memory device.

With the replacement of conventional hard disks by solid-state drives (SSDs), NAND flash memory devices, a type of non-volatile memory, have been widely commercialized. Recently, with the advancements in miniaturization and high integration, vertical NAND flash memory devices in which a plurality of memory cells are stacked in a direction perpendicular to a substrate have been developed.

As the number of stacked memory cell layers in vertical NAND flash memory devices increases and their heights decrease, charge migration may occur, which may lead to a deterioration in the charge retention characteristics of memory cells.

### SUMMARY

Some example embodiments include a vertical NAND flash memory device, a method of fabricating the vertical NAND flash memory device, and/or an electronic apparatus including the vertical NAND flash memory device.

Additional aspects will be set forth in part in the description which follows and, in part, will be apparent from the description, or may be learned by practice of various example embodiments in the disclosure.

According to some example embodiments, a vertical NAND flash memory device includes a plurality of cell strings each extending in a direction perpendicular to a substrate. Each of the plurality of cell strings includes a channel layer, a charge trap layer on the channel layer and including an amorphous oxide, at least one insertion layer inside the charge trap layer, and a plurality of gate electrodes on the charge trap layer.

Alternatively or additionally according to some example embodiments, a method of fabricating a vertical NAND flash memory device includes alternately stacking a plurality of gate electrodes and a plurality of interlayer insulating layers on a substrate, forming a channel hole through the plurality of gate electrodes and the plurality of interlayer insulating layers, forming a charge trap layer including an amorphous ternary oxide on an inner wall of the channel hole, forming an insertion layer inside the charge trap layer, forming a channel layer on the charge trap layer; and heat treating the charge trap layer. The insertion layer is configured to reduce the likelihood of crystallization of the amorphous ternary oxide included in the charge trap layer during the heat treating of the charge trap layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view schematically illustrating a vertical NAND flash memory device according to some example embodiments;

FIG. 2 is a perspective view illustrating a cell string shown in FIG. 1;

FIG. 3 is an equivalent circuit diagram of the vertical NAND flash memory device shown in FIG. 1;

FIG. 4 is an enlarged cross-sectional view illustrating a portion A of FIG. 1;

FIG. 5A is a view illustrating a first charge trap layer including an amorphous high-k material;

FIG. 5B is view illustrating a second charge trap layer including a crystalline high-k material;

FIG. 6 is a graph illustrating experimental results of measuring charge losses of the first and second charge trap layers shown in FIGS. 5A and 5B;

FIG. 7A is a view schematically illustrating an electronic band structure of a SiN charge trap layer;

FIG. 7B is a view illustrating an electronic band structure of an HfAlO charge trap layer including a SiO insertion layer;

FIGS. 8A and 8B are transmission electron microscopy (TEM) images of HfAlO (24 cycles) deposited on a Si substrate using an atomic layer deposition (ALD) process followed by heat treatment;

FIGS. 9A and 9B are TEM images of SiO (25 cycles)/lower HfAlO (18 cycles)/SiO (1 cycle)/upper HfAlO (18 cycles) sequentially deposited on a Si substrate using an ALD process followed by heat treatment;

FIGS. 10A and 10B are TEM images of SiO (25 cycles)/lower HfAlO (18 cycles)/SiO (2 cycles)/upper HfAlO (18 cycles) sequentially deposited on a Si substrate using an ALD process followed by heat treatment;

FIGS. 11A and 11B are TEM images of SiO (25 cycles)/lower HfAlO (18 cycles)/SiO (5 cycles)/upper HfAlO (18 cycles)/SiO (25 cycles) sequentially deposited on a Si substrate using an ALD process followed by heat treatment;

FIG. 12 is a cross-sectional view illustrating a charge trap layer and insertion layers as another example of a structure applicable to a vertical NAND flash memory device according to some example embodiments;

FIGS. 13A to 13G are views illustrating a method of fabricating a vertical NAND flash memory device according to some example embodiments;

FIG. 14 is a block diagram schematically illustrating a display driver integrated circuit (display driver IC or DDI) and a display apparatus including the DDI, according to some example embodiments;

FIG. 15 is a block diagram illustrating an electronic apparatus according to some example embodiments;

FIG. 16 is a block diagram illustrating an electronic apparatus according to some example embodiments;

FIG. 17 is a conceptual view schematically illustrating a device architecture applicable to an electronic apparatus according to some example embodiments; and

FIG. 18 is a conceptual view schematically illustrating a device architecture applicable to an electronic apparatus according to some example embodiments.

### DETAILED DESCRIPTION

Reference will now be made in detail to some embodiments, examples of which are illustrated in the accompanying drawings, wherein like reference numerals refer to like elements throughout. In this regard, the present embodiments may have different forms and should not be construed as being limited to the descriptions set forth herein. Accordingly, various example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, some example embodiments will be described with reference to the accompanying drawings. In the drawings, like reference numerals refer to like elements, and the sizes of elements may be exaggerated for clarity of illustration. The example embodiments described herein are for illustrative purposes only, and various modifications may be made therein.

In the following description, when an element is referred to as being “above” or “on” another element, it may be directly on an upper, lower, left, or right side of the other element while making contact with the other element or may be above an upper, lower, left, or right side of the other element without making contact with the other element. The terms of a singular form may include plural forms unless otherwise mentioned. It will be further understood that the terms “comprises” and/or “comprising” used herein specify the presence of stated features or elements, but do not preclude the presence or addition of one or more other features or elements.

An element referred to with the definite article or a demonstrative determiner may be construed as the element or the elements even though it has a singular form. Operations of a method may be performed in an appropriate order unless explicitly described in terms of order or described to the contrary, and are not limited to the stated order thereof.

In the disclosure, terms such as “unit” or “module” may be used to denote a unit that has at least one function or operation and is implemented with hardware, software, or a combination of hardware and software.

Furthermore, line connections or connection members between elements depicted in the drawings represent functional connections and/or physical or circuit connections by way of example, and in actual applications, they may be replaced or embodied with various additional functional connections, physical connections, or circuit connections.

Examples or exemplary terms are just used herein to describe technical ideas and should not be considered for purposes of limitation unless defined by the claims.

In vertical NAND flash memory devices, key reliability factors include the retention of data, that is, the ability to store charge in a charge trap layer for a prolonged period. When the distance between memory cells is reduced to increase memory density in vertical NAND flash memory devices, charges (e.g., electrons and/or holes) trapped in memory cells may migrate between the memory cells, leading to a deterioration in charge retention characteristics.

In vertical NAND flash memory devices, charge may migrate from a charge trap layer to a tunneling dielectric layer through trap-assisted tunneling and/or thermal emission in a direction perpendicular to the charge trap layer The extent of this charge migration may be determined by a conduction band offset (CBO) at an interface between the charge trap layer and the tunneling dielectric layer.

In a direction parallel to the charge trap layer, charge migration may occur through lateral migration caused by the gradient of charge concentration. Charge migration in the direction parallel to the charge trap layer may be dominated by the Poole-Frenkel effect, that is, by Poole-Frenkel tunneling.

Current density by Poole-Frenkel tunneling may be expressed by the following Poole-Frenkel Conduction Equation (Equation 1):

$$J = q μ {N}_{c} E exp ( \frac{- q ( {E}_{T} - \sqrt{qE / πε} )}{κ T} ) \qquad ( equation 1 )$$

where, J is the current density, q is the electric charge, μ is the carrier (electron or hole) mobility, N_{c} is the density of states in the conduction band, E is the: electric field, E_{T} is the trap energy, ε is the permittivity, κ is Boltzmann's constant, and T is the temperature measured from absolute zero.

Charge migration occurring in a direction parallel to a charge trap layer due to Poole-Frenkel tunneling may be determined by trap energy E_{T} and by the trap density N_{T} in the charge trap layer. Trap energy refers to a voltage barrier that an electron overcomes to move from one atom to another atom within a material such as within a crystalline material. That is, trap energy refers to the depth of a trap state relative to the conduction band minimum (CBM) of a material. Trap density refers to the number of trapped charges per unit volume. Trap density may be calculated by a charge pumping method. Charge retention characteristics in a direction parallel to a charge trap layer may be improved by high trap energy and high trap density.

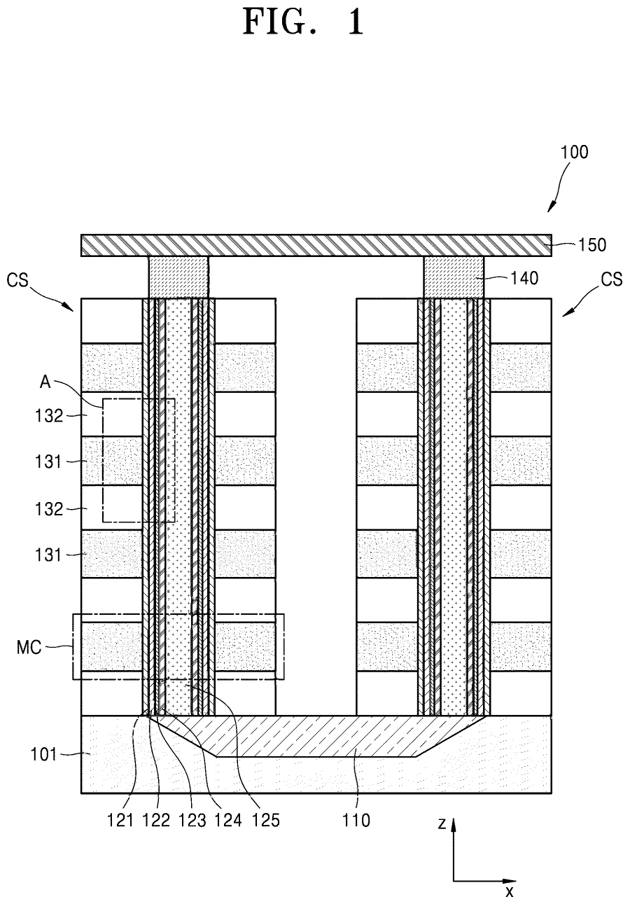

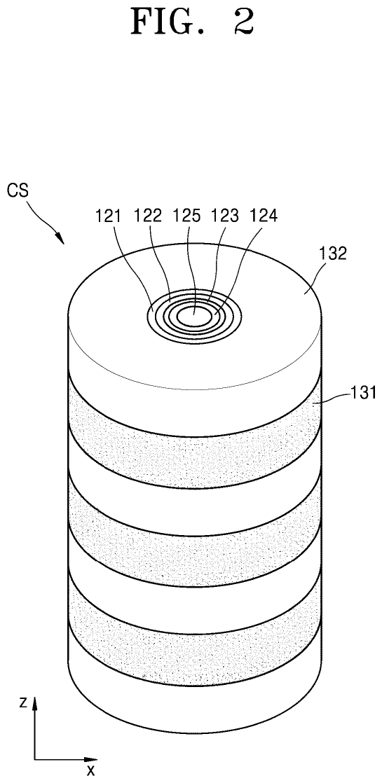

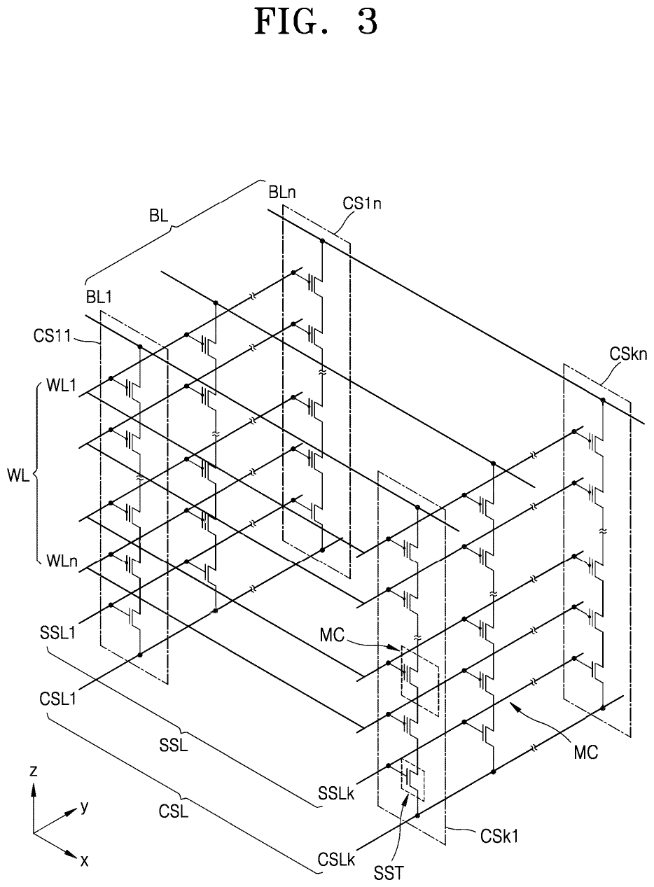

FIG. 1 is a cross-sectional view schematically illustrating a vertical NAND flash memory device 100 according to some example embodiments, and FIG. 2 is a perspective view illustrating a cell string CS shown in FIG. 1. FIG. 3 is an equivalent circuit diagram of the vertical NAND flash memory device 100 shown in FIG. 1.

Referring to FIGS. 1 and 2, a plurality of cell strings CS are provided on a substrate 101. Here, the cell strings CS may be arranged in various forms on the substrate 101. Each of the cell strings CS may extend in a direction (Z-axis direction) perpendicular to the substrate 101.

The substrate 101 may include a silicon material doped, e.g., lightly doped, with a first-type dopant. For example, the substrate 101 may include a silicon material (e.g., a single-crystal silicon material) doped with a p-type dopant such as boron. For instance, the substrate 101 may include a p-type well (for example, a pocket p-well). The substrate 101 includes a common source region 110. For example, the common source region 110 may be doped with a second-type dopant unlike the substrate 101. For instance, the common source region 110 may be doped with an n-type dopant such as one or more of phosphorus or arsenic. The common source region 110 may be connected to a common source line CSL (refer to FIG. 3).

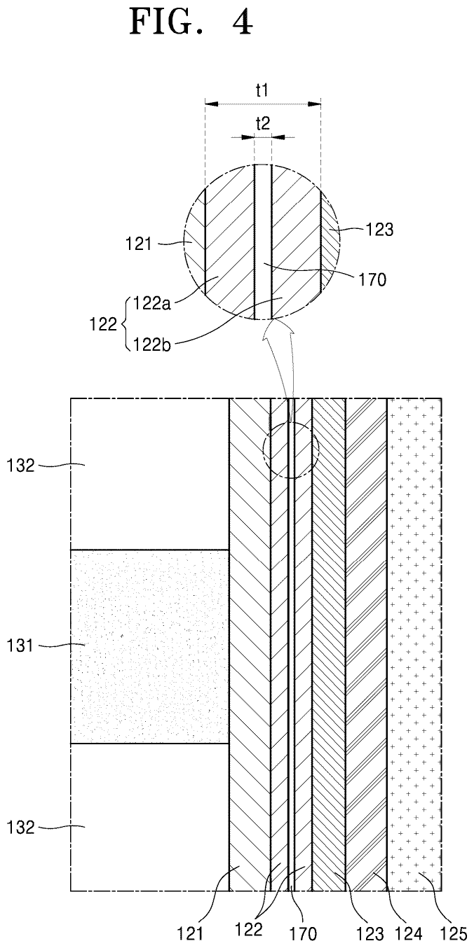

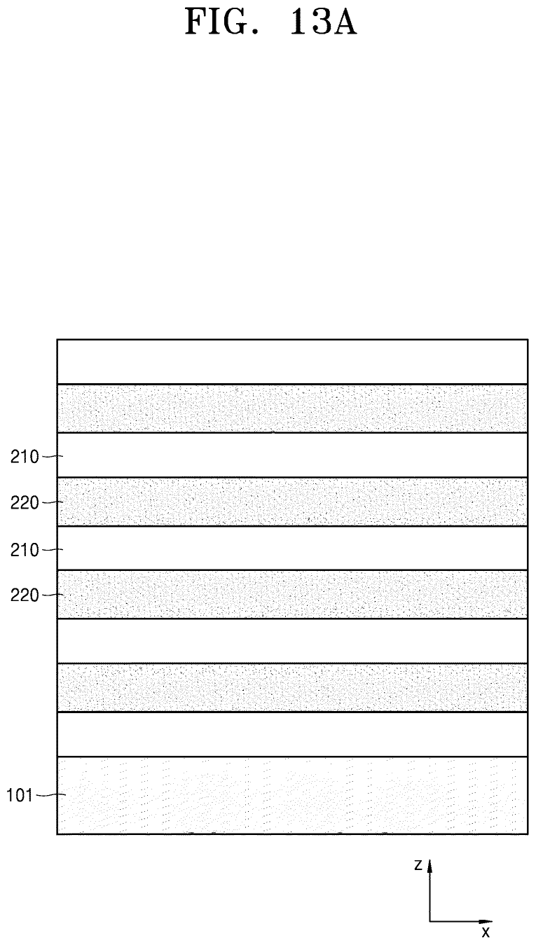

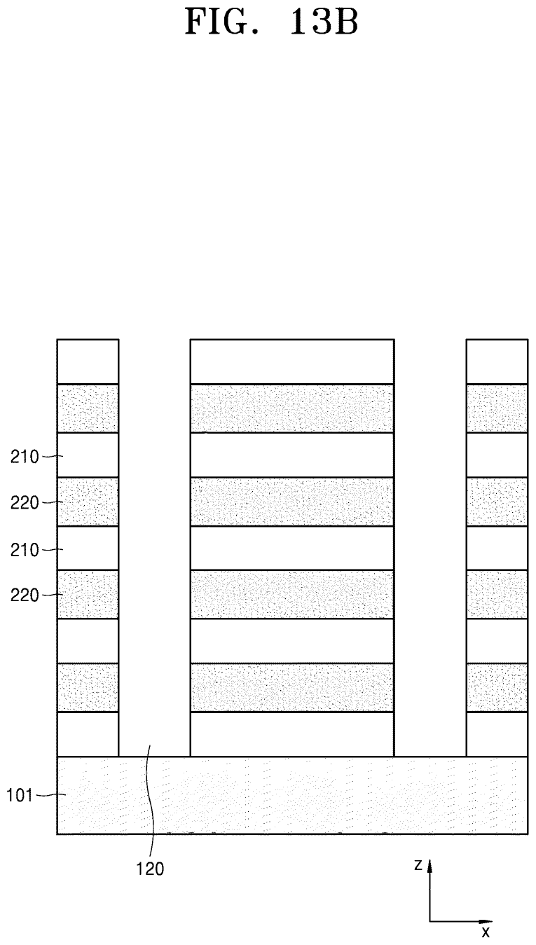

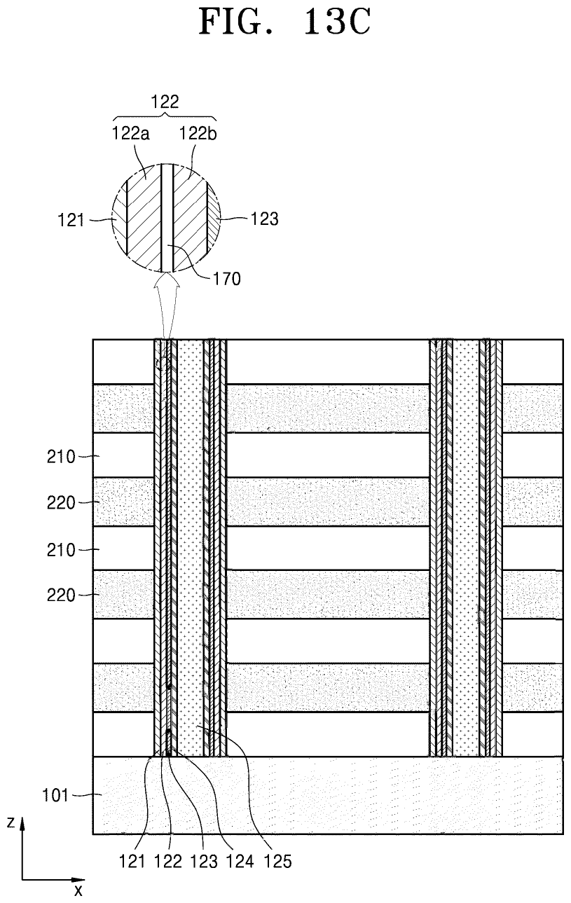

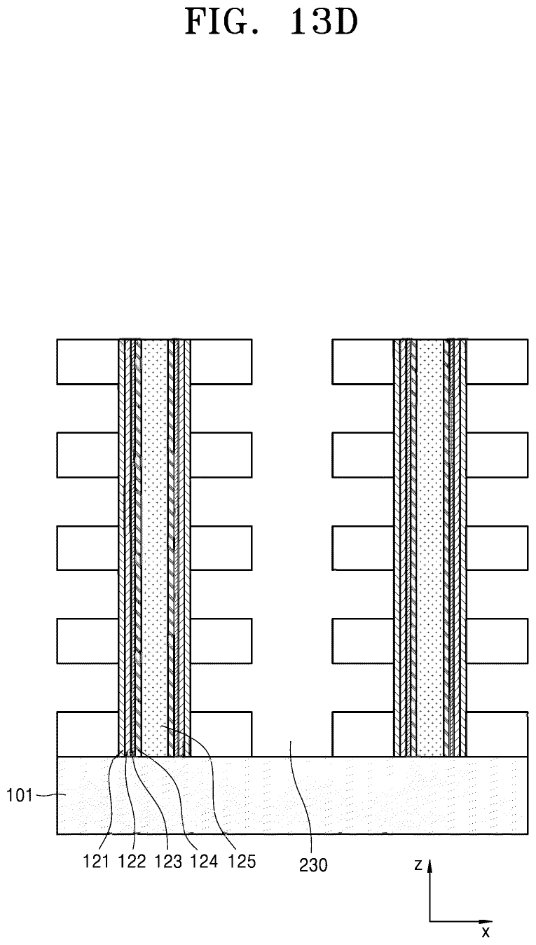

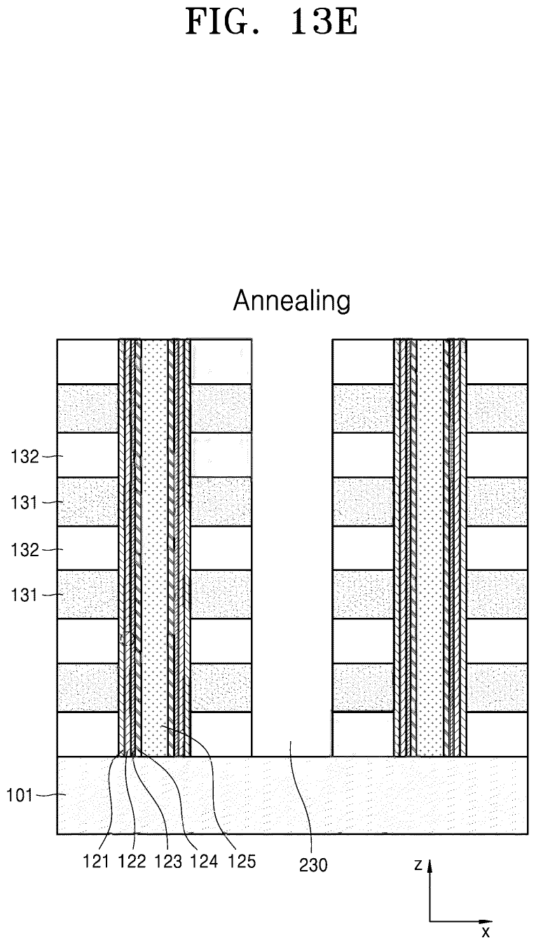

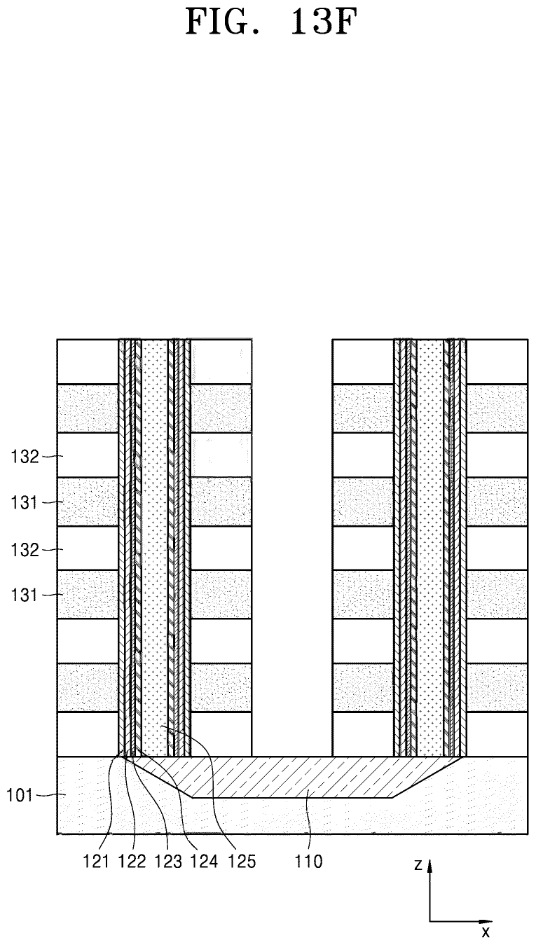

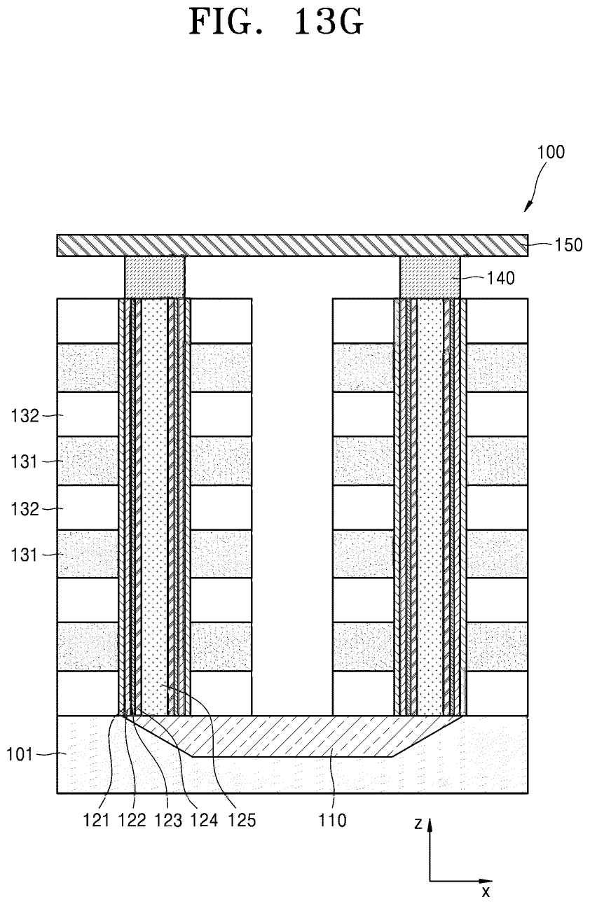

Each of the cell strings CS may include a plurality of memory cells MC arranged at intervals in the direction (Z-axis direction) perpendicular to the substrate 101. The cell strings CS may each have, for example, a cylindrical shape such as a straight or tapered cylindrical shape, but example embodiments are not limited thereto. In each of the cell strings CS, a plurality of gate electrodes 131 and a plurality of interlayer insulating layers 132 are alternately arranged. A channel hole 120 (refer to FIG. 13B) penetrates the gate electrodes 131 and the interlayer insulating layers 132 while extending in the direction perpendicular to the substrate 101. A charge trap layer 122 and a channel layer 124 are sequentially provided on an inner wall of the channel hole 120, and an insertion layer 170 (refer to FIG. 4) is provided in the charge trap layer 122.

A thickness of and/or a material composition of each of the plurality of gate electrodes 131 may be the same as each other; however, example embodiments are not limited thereto, and at least one of the plurality of gate electrodes 131 may have a different thickness than, and/or a different material composition than, at least another of the plurality of gate electrodes 131. A thickness of and/or a material composition of each of the insulating layers 132 may be the same as each other; however, example embodiments are not limited thereto, and at least one of the plurality of insulating layers 132 may have a different thickness than, and/or a different material composition than, at least another of the plurality of insulating layers 132.

A barrier dielectric layer 121 is provided between each of the gate electrodes 131 and the charge trap layer 122, and a tunneling dielectric layer 123 is provided between the charge trap layer 122 and the channel layer 124. A filling insulating layer 125 is provided inside the channel layer 124 to fill the channel hole 120.

Each of the gate electrodes 131 may form a memory cell MC, together with the barrier dielectric layer 121, the charge trap layer 122, the insertion layer 170, the tunneling dielectric layer 123, and the channel layer 124 that correspond to the gate electrode 131 and are provided in a first direction (X-axis direction) parallel to the substrate 101. A drain 140 connected to the channel layer 124 may be provided, for example on an upper portion of each of the cell strings CS, and a silicon material doped with a second-type dopant may be included in the drain 140. For example, the drain 140 may include a silicon material doped with an n-type dopant. The drain 140 may be electrically connected to a bit line 150 through a contact plug. In some cases, the drain 140 may be counterdoped, e.g., may also include p-type dopants at a lower concentration than n-type dopants; example embodiments are not limited thereto.

When a voltage is applied to the gate electrode 131 of a memory cell MC, a charge may be transferred from the channel layer 124 corresponding to the gate electrode 131 to the charge trap layer 122 through the tunneling dielectric layer 123 and may be trapped in the charge trap layer 122. In this manner, information may be stored in each of the memory cells MC.

Referring to FIG. 3, k*n cell strings CS may be provided on the substrate 101 in a matrix form and may be named CSij (1≤i≤k, 1≤j≤n) based on row and column positions. Each of the cell strings Csij is connected to a bit line BL, a string select line SSL, word lines WL, and a common source line CSL. Here, k may be less than, greater than, or equal to n.

Each of the cell strings CSij includes memory cells MC and a string select transistor SST. The memory cells MC and the string select transistor SST of each of the cell strings CSij may be stacked in the direction perpendicular to the substrate 101.

Rows of the cell strings CS may be connected to different string select lines SSL1 to SSLk. For example, the string select transistors SST of the cell strings CS11 to CS1n may be commonly connected to the string select line SSL1. The string select transistors SST of the cell strings CSk1 to CSkn may be commonly connected to the string select line SSLk.

Columns of the cell strings CS are connected to different bit lines BL1 to BLn. For instance, the memory cells MC and the string select transistors SST of the cell strings CS11 to CSk1 may be commonly connected to the bit line BL1 (bit line 150), and the memory cells MC and the string selection transistors SST of the cell strings CS1n to CSkn may be commonly connected to the bit line BLn.

Rows of the cell strings CS may be connected to different common source lines CSL1 to CSLk. For example, the string select transistors SST of the cell strings CS11 to CS1n may be commonly connected to the common source line CSL1, and the string select transistors SST of the cell strings CSk1 to CSkn may be commonly connected to the common source line CSLk.

Memory cells MC arranged at the same height from the substrate 101 or the string select transistors SST may be commonly connected to one word line WL, and memory cells MC arranged at different heights may be connected to different word lines WL1 to WLn.

The circuit structure shown in FIG. 3 is only an example. For instance, the number of rows of the cell strings CS may be increased or decreased. As the number of rows of the cell strings CS varies, the number of string select lines SSL connected to the rows of the cell strings CS and the number of cell strings CS connected to each of the bit lines BL (bit lines 150) may also vary. As the number of rows of the cell strings CS varies, the number of common source lines CSL connected to the rows of the cell strings CS may also vary.

The number of columns of the cell strings CS may be increased or decreased. As the number of columns of the cell strings CS varies, the number of bit lines BL connected to the columns of the cell strings CS and the number of cell strings CS connected to each of the string select lines SSL may also vary.

The height of the cell strings CS may also be increased or decreased. For example, the number of memory cells MC stacked in each of the cell strings CS may be increased or decreased. As the number of memory cells MC stacked in each of the cell strings CS varies, the number of word lines WL may also vary. For example, the number of string select transistors SST provided in each of the cell strings CS may be increased. As the number of string select transistors SST provided in each of the cell strings CS varies, the number of string select lines SSL or the number of common source lines CSL may also vary. When the number of string select transistors SST increases, the string select transistors SST may be stacked in the same manner as the memory cells MC.

For example, writing (programming and erasing) and/or reading may be performed in units of rows of the cell strings CS. The cell strings CS may be selected in units of rows through the common source lines CSL. The cell stings CS may also be selected in units of rows through the string select lines SSL. In addition, voltage may be applied to the common source lines CSL in units of at least two common source lines CSL. Voltage may be applied to all the common source lines CSL by treating all the common source lines CSL as a single unit.

In a selected row of the cell strings CS, writing and reading may be performed in units of pages. A page may refer to a row of memory cells connected to one word line WL. In a selected row of the cell strings CS, memory cells MC may be selected in units of pages by the word lines WL.

For example, when a memory cell MC targeted for writing is selected, a gate voltage of the selected memory cell MC is adjusted to prevent or reduce the likelihood of and/or impact from channel formation, that is, to bring the selected memory cell MC into a channel-off state, and gate voltages of unselected memory cells MC are adjusted to bring the unselected memory cells MC into a channel-on state. As a result, a charge may tunnel through the tunneling dielectric layer 123 and become trapped in the charge trap layer 122 of the selected memory cell MC due to a voltage applied to a common source line CSL and a bit line BL, and thus, intended data (logical 1 or 0) may be recorded in the selected memory cell MC.

During a read operation, a selected memory cell MC may be read in a similar manner. That is, after adjusting gate voltages applied to the gate electrodes 131 of the memory cells CS to turn off a channel of the selected memory cell MC and turn on channels of unselected memory cells MC, a current flowing through the selected memory cell MC may be measured using a voltage Vread applied between a common source line CSL and a bit line BL to determine the state (1 or 0) of the selected memory cell MC.

Referring back to FIGS. 1 and 2, the gate electrodes 131 and the interlayer insulating layers 132 are alternately stacked in the direction perpendicular to the substrate 101. Each of the interlayer insulating layers 132 and each of the gate electrodes 131 may be parallel to the substrate 101. Each of the memory cells MC may be formed by a gate electrode 131, and the barrier dielectric layer 121, the charge trap layer 122, the insertion layer 170, the tunneling dielectric layer 123, and the channel layer 124 that are provided at positions corresponding to the gate electrode 131.

FIG. 4 is an enlarged view illustrating a portion A of FIG. 1.

Referring to FIG. 4, each of the gate electrodes 131 may control the channel layer 124 corresponding to the gate electrode 131 and may include, for example, one or more of a highly conductive metal material, a metal nitride, silicon doped with a dopant, or a two-dimensional conductive material such as but not limited to graphene and/or boron-nitride (BN). However, the listed materials are merely examples, and the gate electrodes 131 may include various other materials. The interlayer insulating layers 132 may act as spacer layers for insulation between the gate electrodes 131. The interlayer insulating layers 132 may include, for example, one or more of silicon oxide, silicon nitride, or the like, but are not limited thereto.

The channel hole 120 (refer to 13B) is formed through the interlayer insulating layers 132 and the gate electrodes 131 in the direction (Z-axis direction) perpendicular to the substrate 101. The channel hole 120 may have, for example, a circular cross-sectional shape. The barrier dielectric layer 121, the charge trap layer 122 including the insertion layer 170 therein, the tunneling dielectric layer 123, and the channel layer 124 are sequentially provided on the inner wall of the channel hole 120. Here, each of the barrier dielectric layer 121, the charge trap layer 122, the tunneling dielectric layer 123, and the channel layer 124 may have a cylindrical shape extending in the direction perpendicular to the substrate 101. The filling insulating layer 125 may be provided inside the channel layer 124 to fill the channel hole 120. The filling insulating layer 125 may include, for example, silicon oxide and/or air, but is not limited thereto.

The channel layer 124 may include a semiconductor material. For example, the channel layer 124 may include one or more of Si, Ge, SiGe, a Group III-V semiconductor, or the like. Alternatively or additionally, the channel layer 124 may include, for example, an oxide semiconductor, a nitride semiconductor, an oxynitride semiconductor, a two-dimensional semiconductor material, quantum dots (QDs), or an organic semiconductor. Here, the oxide semiconductor may include InGaZnO or the like, the two-dimensional semiconductor material may include a transition metal dichalcogenide (TMD) or graphene, and the QDs may include colloidal QDs or nanocrystal structures. However, the listed materials are merely examples, and embodiments are not limited thereto.

The channel layer 124 may include a semiconductor material doped with a first-type dopant, and in some cases with the second-type dopant having a much lower concentration than that of the first-type dopant. The channel layer 124 may include a silicon material doped with the same type as the substrate 101. For example, when the substrate 101 includes a silicon material doped with a p-type dopant, the channel layer 124 may also include a silicon material doped with a p-type dopant.

The barrier dielectric layer 121, the charge trap layer 122 including the insertion layer 170 therein, and the tunneling dielectric layer 123 are provided between each of the gate electrodes 131 and the channel layer 124. The barrier dielectric layer 121 is provided on the inner wall of the channel hole 120 and is in contact with the interlayer insulating layers 132 and the gate electrodes 131. The barrier dielectric layer 121 may include, for example, silicon oxide or a metal oxide, but is not limited thereto. The tunneling dielectric layer 123 through which charge tunneling occurs may include, for example, silicon oxide and/or a metal oxide, but is not limited thereto.

The charge trap layer 122 is provided between the barrier dielectric layer 121 and the tunneling dielectric layer 123. The charge trap layer 122 may store charges introduced from the channel layer 124. For example, charges (for example, electrons) present in the channel layer 124 may be introduced into the charge trap layer 122 by a tunneling effect or the like and may remain fixed within the charge trap layer 122.

The charge trap layer 122 may include an amorphous high-k oxide having a dielectric constant greater than that of SiO2. For instance, the charge trap layer 122 may include AlO, HfO, TaO, ZrO, LaO, GaO, YO, BaO, ScO, WO, TiO, or a ternary oxide including a combination of the listed elements.

For example, the charge trap layer 122 may include an amorphous ternary oxide represented by MAlO (where M is Hf, Ta, Zr, La, Ga, Y, Ba, Sc, W, or Ti, Al is aluminum, and O is oxygen). Here, MAlO refers to MO+AlO formed by alternately depositing MO and AlO layers. For example, HfAlO refers to HfO+AlO formed by alternately depositing HfO and AlO layers. In the charge trap layer 122 including an amorphous ternary oxide represented by MAlO, the ratio of a content of M to a content of (M+Al) may be in a range of about 0.2 to less than about 1.0. For instance, the ratio of the content of M to the content of (M+Al) may be in a range of about 0.5 to less than about 1.0.

The insertion layer 170 including a material different from the material of the charge trap layer 122 is provided in the charge trap layer 122. The charge trap layer 122 may include a first charge trap layer 122a located between the barrier dielectric layer 121 and the insertion layer 170, and a second charge trap layer 122b located between the tunneling dielectric layer 123 and the insertion layer 170. The insertion layer 170 may include a material with a greater bandgap than the material of the charge trap layer 122. For instance, the insertion layer 170 may include at least one selected from SiO, SiN, AlN, and BN. However, the listed materials are merely examples.

The insertion layer 170 may prevent or reduce the likelihood of and/or impact from the amorphous high-k oxide included in the charge trap layer 122 from crystallizing during a subsequent heat treatment process. For example, during a heat treatment process after the charge trap layer 122 including the amorphous high-k oxide is formed, the insertion layer 170 provided inside the charge trap layer 122 may prevent or reduce the formation of nuclei that are greater than a critical size required for crystal growth of the amorphous high-k oxide, and thus, the amorphous high-k oxide may remain in an amorphous state.

For example, the charge trap layer 122 may have a thickness (t1−t2) of about 50 Å to about 80 Å. For example, the charge trap layer 122 may have a thickness (t1−t2) of about 60 Å to about 70 Å. For example, the insertion layer 170 may have a thickness t2 of about 2 Å to about 15 Å For example, the insertion layer 170 may have a thickness t2 of about 4 Å to about 10 Å. The insertion layer 170 may be located in an inner middle portion of the charge trap layer 122 but is not limited thereto.

Silicon nitride (SiN), commonly used as a material of charge trap layers, may cause charge migration due to a charge distribution gradient between adjacent memory cells. To address this, high-k oxides having large trap energy ET may be used as materials of charge trap layers. However, most high-k oxides are thermally unstable, and thus, during high-temperature heat treatment processes in memory device manufacturing, most high-k oxides crystallize into a polycrystalline form due to low crystallization threshold temperatures thereof. In some example embodiments, the insertion layer 170 is provided inside the charge trap layer 122 to prevent or reduce crystallization during a heat treatment process. Thus, the amorphous high-k oxide of the charge trap layer 122 may remain in an amorphous state even under high-temperature heat treatment process conditions.

As described above, in the vertical NAND flash memory device 100 of some example embodiments, the insertion layer 170 is provided in the charge trap layer 122 to prevent or reduce crystallization during heat treatment processes. This improves thermal stability, allowing the amorphous high-k oxide of the charge trap layer 122 to remain amorphous even at high temperatures. The amorphous high-k oxide of the charge trap layer 122 has greater permittivity than silicon nitride (SiN), and thus, the operating voltage of the vertical NAND flash memory device 100 may be reduced. Alternatively or additionally, the large trap energy E_{T} and high trap density N_{T} of the amorphous high-k oxide may improve charge retention characteristics and may thus increase a memory window. Alternatively or additionally, because the insertion layer 170 provided in the charge trap layer 122 has a greater bandgap than the charge trap layer 122, charge migration may be further suppressed, and thus, charge retention characteristics may be further improved.

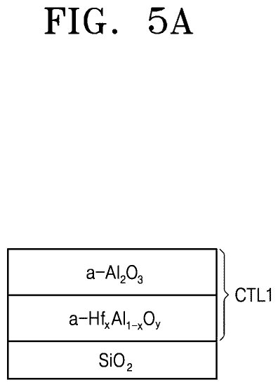

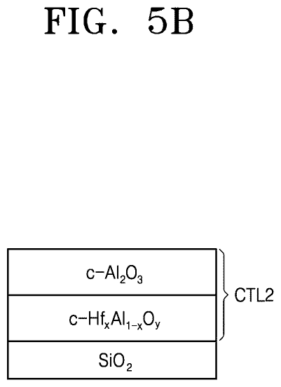

FIG. 5A is a view illustrating a first charge trap layer CTL1 including an amorphous high-k material, and FIG. 5B is view illustrating a second charge trap layer CTL2 including a crystalline high-k material (for example, a polycrystalline high-k material).

Referring to FIG. 5A, the first charge trap layer CTL1 includes amorphous HfAlO (a-HfₓAl₁₋ₓOy) and amorphous AlO (a-Al₂O₃) that are sequentially deposited on SiO2. Referring to FIG. 5B, the second charge trap layer CTL2 includes polycrystalline HfAlO (c-HfₓAl₁₋ₓOy) and polycrystalline AlO (c-Al₂O₃) that are sequentially deposited on SiO2. The second charge trap layer CTL2 shown in FIG. 5B may be formed by performing a heat treatment process on the first charge trap layer CTL1 shown in FIG. 5A to crystallize the amorphous HfAlO (a-HfₓAl₁₋ₓOy) and amorphous AlO (a-Al₂O₃).

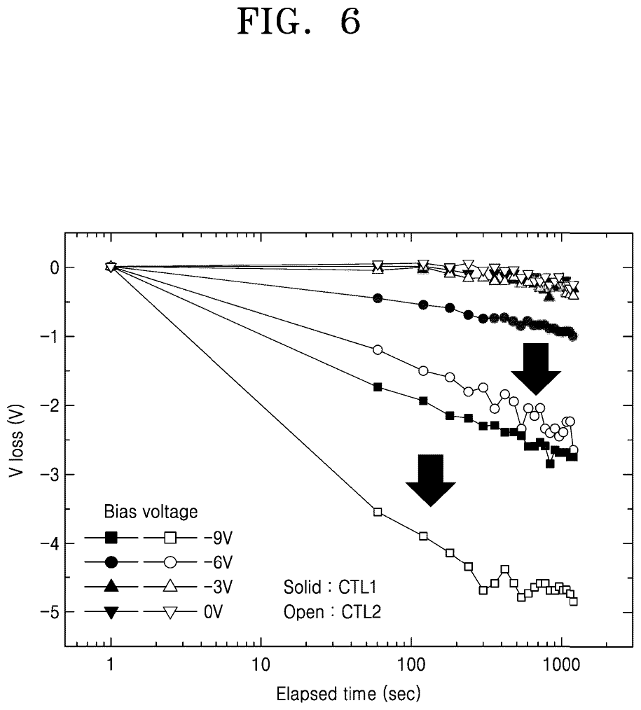

FIG. 6 is a graph illustrating results of an experiment performed to measure charge losses of the first and second charge trap layers CTL1 AND CTL2 shown in FIGS. 5A and 5B.

As shown in FIG. 6, the charge loss of the second charge trap layer CTL2 is greater than the charge loss of the first charge trap layer CTL1. The polycrystalline materials of the second charge trap layer CTL2 contain defects such as grain boundaries through which charge leakage may occur, and thus, the charge loss of the second charge trap layer CTL2, which is polycrystalline, may be greater than the charge loss of the first charge trap layer CTL1, which is amorphous.

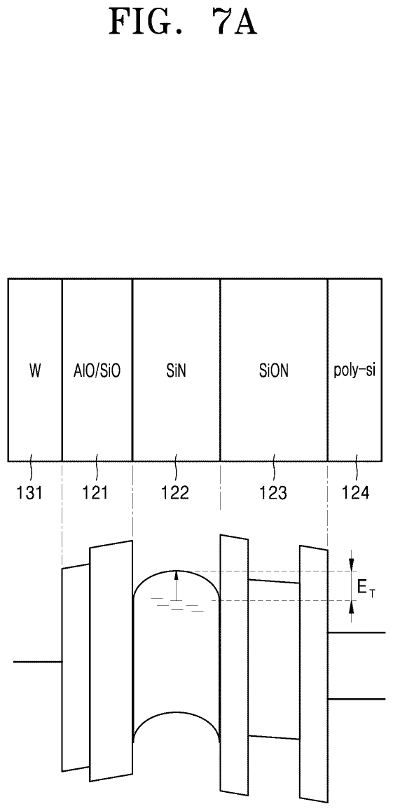

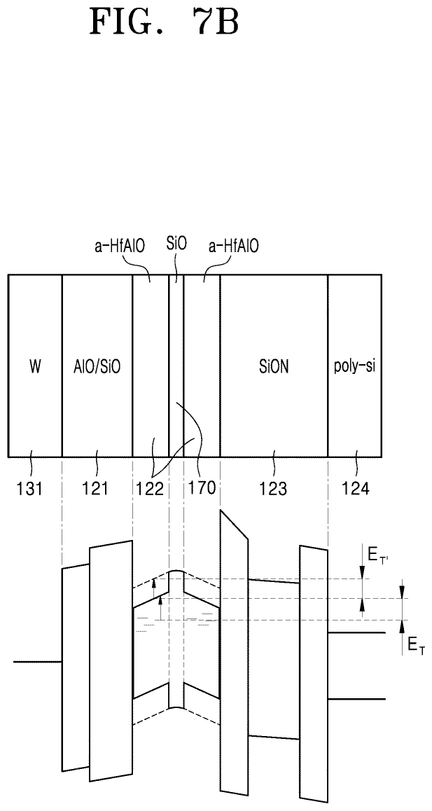

FIG. 7A is a view schematically illustrating an electronic band structure (Fermi structure) of a SiN charge trap layer 122. FIG. 7B is a view schematically illustrating an electronic band structure of an amorphous HfAlO charge trap layer 122 in which a SiO insertion layer 170 is provided. In each of FIGS. 7A and 7B, a gate electrode 131, a barrier dielectric layer 121, a tunneling dielectric layer 123, and a channel layer 124 include tungsten (W), AlO/SiO, SiON, and poly-Si, respectively.

Referring to FIGS. 7A and 7B, the amorphous HfAlO charge trap layer 122, shown in FIG. 7B and provided with the SiO insertion layer 170 therein, may have trap energy E_{T} contributed by amorphous HfAlO and additional trap energy E_{T} contributed by SiO. This combination may result in improved charge retention characteristics compared to the SiN charge trap layer 122 shown in FIG. 7A.

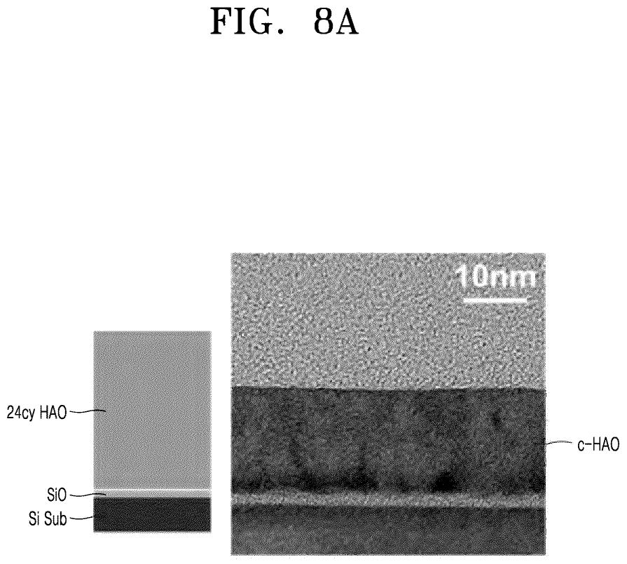

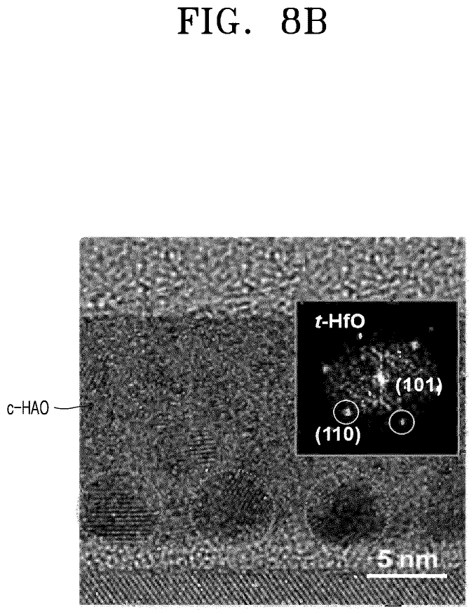

FIGS. 8A and 8B are transmission electron microscopy (TEM) images of 24 cy HAO deposited on a Si substrate through an atomic layer deposition (ALD) process. In FIG. 8A, “24 cy HAO” refers to HAO (that is, HfAlO) formed by alternately depositing HfO and AlO for 24 cycles using the ALD process, and “c-HAO” refers to polycrystalline HAO. This terminology applies to the following description. A left side of FIG. 8A shows the 24 cy HAO deposited on the Si substrate by the ALD process A SiO oxide layer is naturally formed on a surface of the Si substrate. A right side of FIG. 8A shows a TEM image of the 24 cy HAO deposited on the Si substrate and then heat treated at about 1,100° C. through a post deposition annealing (PDA) process. FIG. 8B shows an enlarged view of the TEM image shown in FIG. 8A, along with an image obtained through a Fourier Transform, i.e., a Fast Fourier Transform (FFT). Referring to FIGS. 8A and 8B, the 24 cy HAO deposited on the Si substrate in an amorphous state was crystallized through the heat treatment, transforming into polycrystalline HAO (c-HAO). For example, the inlet showing the Fourier Transform has pronounced amplitudes at certain orientations (110) and (101).

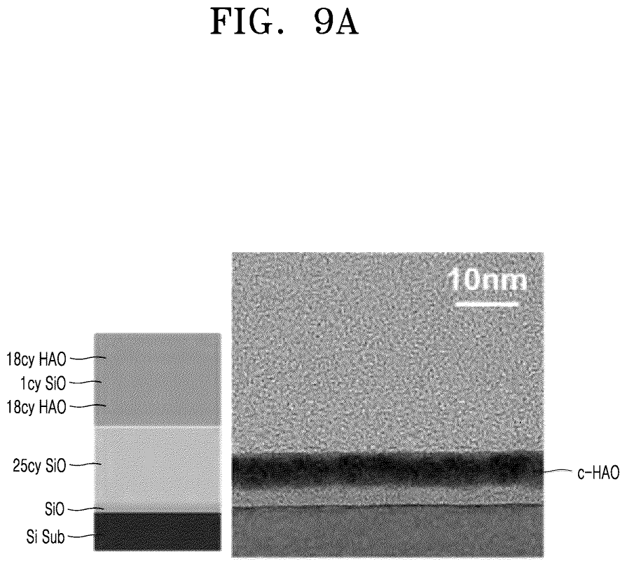

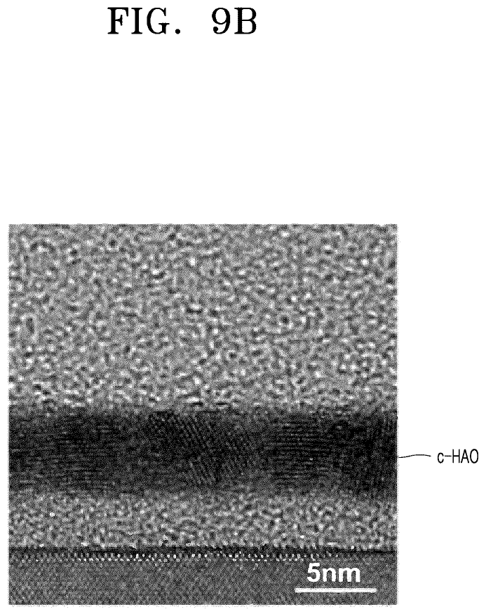

FIGS. 9A and 9B are TEM images of 25 cy SiO/18 cy HAO/1 cy SiO/18 cy HAO sequentially deposited on a Si substrate using an ALD process, followed by heat treatment. In FIG. 9A, “25 cy SiO” refers to SiO formed by depositing SiO for 25 cycles using the ALD process. This terminology applies to the following description. A left side of FIG. 9A shows the 25 cy SiO/18 cy HAO/1 cy SiO/18 cy HAO sequentially deposited on the Si substrate using the ALD process. A right side of FIG. 9A shows a TEM image of the 25 cy SiO/18 cy HAO/1 cy SiO/18 cy HAO deposited on the Si substrate and then heat treated at about 1,100° C. through a PDA process. FIG. 9B shows an enlarged view of the TEM image shown in FIG. 9A. Referring to FIGS. 9A and 9B, the 18 cy HAO (lower HAO) and the 18 cy HAO (upper HAO) deposited on the Si substrate were crystallized through the heat treatment, transforming into a single polycrystalline HAO (c-HAO) layer, and the 1 cy SiO disappeared during the heat treatment.

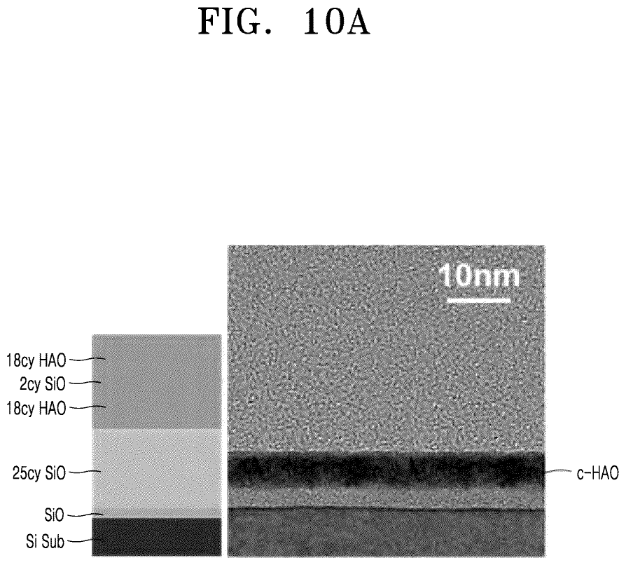

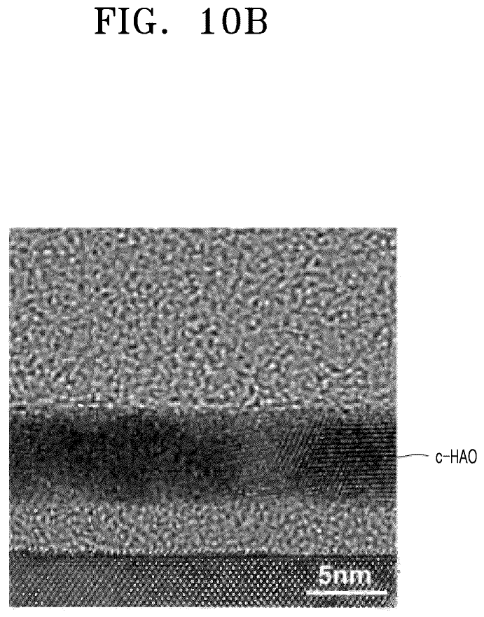

FIGS. 10A and 10B are TEM images of 25 cy SiO/18 cy HAO/2 cy SiO/18 cy HAO sequentially deposited on a Si substrate using an ALD process, followed by heat treatment. A left side of FIG. 10A shows the 25 cy SiO/18 cy HAO/2 cy SiO/18 cy HAO sequentially deposited on the Si substrate using the ALD process. A right side of FIG. 10A shows a TEM image of the 25 cy SiO/18 cy HAO/2 cy SiO/18 cy HAO deposited on the Si substrate and then heat treated at about 1,100° C. through a PDA process. FIG. 10B shows an enlarged view of the TEM image shown in FIG. 10A. Referring to FIGS. 10A and 10B, the 18 cy HAO (lower HAO) and the 18 cy HAO (upper HAO) deposited on the Si substrate were crystallized through the heat treatment, transforming into a single polycrystalline HAO (c-HAO) layer, and the 2 cy SiO disappeared during the heat treatment.

Results shown in FIGS. 9A, 9B, 10A, and 10B show that when SiO having a thickness of less than about 2 nm (for example, a thickness formed by 2 cycles or fewer) is provided between 18 cy HAO (lower HAO) and 18 cy HAO (upper HAO), it is difficult to prevent or reduce the 18 cy HAO (lower HAO) and the 18 cy HAO (upper HAO) from crystallizing during heat treatment.

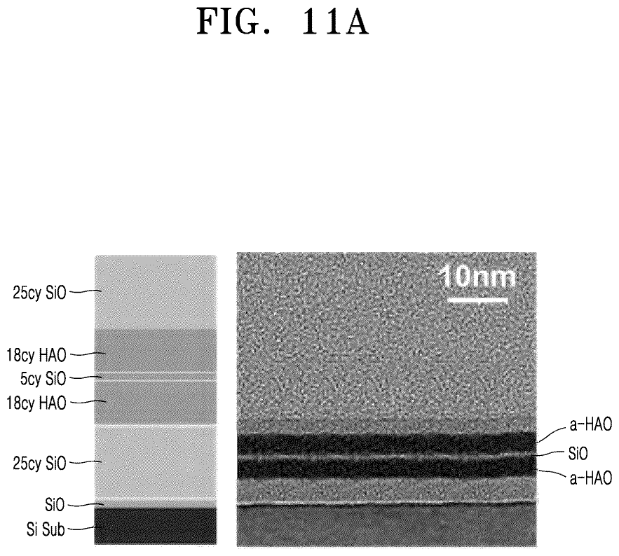

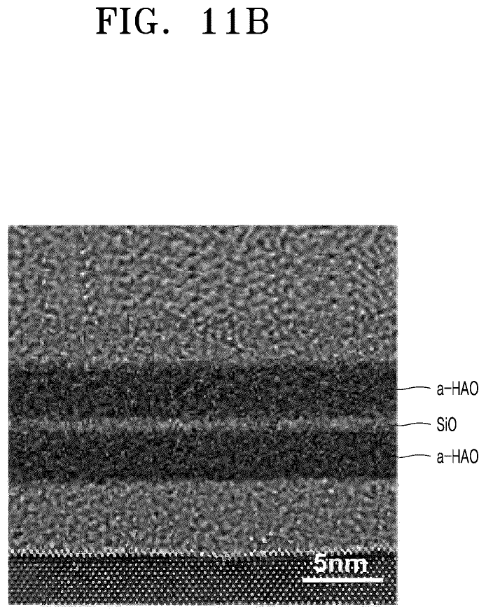

FIGS. 11A and 11B are TEM images of 25 cy SiO/18 cy HAO/5 cy SiO/18 cy HAO/25 cy SiO sequentially deposited on using an ALD process, followed by heat treatment. In FIG. 11A, “a-HAO” refers to amorphous HAO. A left side of FIG. 11A shows the 25 cy SiO/18 cy HAO/5 cy SiO/18 cy HAO/25 cy SiO sequentially deposited on the Si substrate using the ALD process. A right side of FIG. 11A shows a TEM image of the 25 cy SiO/18 cy HAO/5 cy SiO/18 cy HAO/25 cy SiO deposited on the Si substrate and then heat treated at about 1,100° C. through a PDA process. FIG. 11B shows an enlarged view of the TEM image shown in FIG. 11A. Referring to FIGS. 11A and 11B, the 18 cy HAO (lower HAO) and the 18 cy HAO (upper HAO), which were deposited on the Si substrate, remained in an amorphous state (a-HAO) without crystallization during the heat treatment, and heat-treated SiO remained between the 18 cy HAO (lower HAO) and the 18 cy HAO (upper HAO).

Results shown in FIGS. 11A and 11B show that when SiO having a thickness of about 2 nm or more (for example, a thickness formed by 3 cycles or more) is provided between 18 cy HAO (lower HAO) and 18 cy HAO (upper HAO), the SiO prevents or reduces the 18 cy HAO (lower HAO) and the 18 cy HAO (upper HAO) from crystallizing during heat treatment.

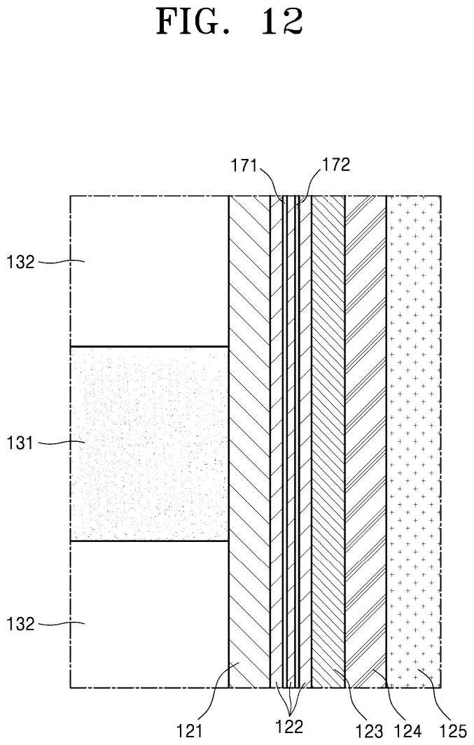

FIG. 12 is a cross-sectional view illustrating first and second insertion layers 171 and 172 as another example of a structure applicable to the vertical NAND flash memory device 100 according to some example embodiments. The following description focuses on differences from the previous description.

Referring to FIG. 12, a charge trap layer 122 is provided between a barrier dielectric layer 121 and a tunneling dielectric layer 123. The charge trap layer 122 may include an amorphous high-k oxide. For example, the charge trap layer 122 may include one or more of AlO, HfO, TaO, ZrO, LaO, GaO, YO, BaO, ScO, WO, TiO, or a ternary oxide including a combination of the listed elements. For instance, the charge trap layer 122 may include an amorphous ternary oxide represented by MAlO (where M is Hf, Ta, Zr, La, Ga, Y, Ba, Sc, W, or Ti, Al is aluminum, and O is oxygen). Here, MAlO refers to MO+AlO formed by alternately depositing MO and AlO layers. For example, HfAlO refers to HfO+AlO formed by alternately depositing HfO and AlO layers. In the charge trap layer 122 including an amorphous ternary oxide represented by MAlO, the ratio of a content of M to a content of (M+Al) may range from about 0.2 to less than about 1.0. For instance, the ratio of the content of M to the content of (M+Al) may range from about 0.5 to less than about 1.0.

The first and second insertion layers 171 and 172 are provided inside the charge trap layer 122. The first and second insertion layers 171 and 172 may include a material with a larger bandgap than the material of the charge trap layer 122. The first and second insertion layers 171 and 172 may include, for example, at least one selected from SiO, SiN, AlN, and BN. However, the listed materials are merely examples. The first and second insertion layers 171 and 172 may include the same, or different, materials from one another, and may have the same, or different, thicknesses as one another.

The first and second insertion layers 171 and 172 may prevent or reduce the amorphous high-k oxide of the charge trap layer 122 from crystallizing during a subsequent heat treatment process. For example, each of the first and second insertion layers 171 and 172 may have a thickness of about 2 Å to about 15 Å. For instance, each of the first and second insertion layers 171 and 172 may have a thickness of about 4 Å to about 10 Å. In the current embodiment, two insertion layers 171 and 172 are provided inside the charge trap layer 122. However, this is merely an example. In other embodiments, three or more insertion layers may be provided inside the charge trap layer 122.

FIGS. 13A to 13G are views illustrating a method of fabricating a vertical NAND flash memory device 100 according to some example embodiments.

Referring to FIG. 13A, first and second insulating material layers 210 and 220 are alternately stacked on a substrate 101. The first and second insulating material layers 210 and 220 may be alternately stacked in a direction (X-axis direction) perpendicular to a surface of the substrate 101. The first and second insulating material layers 210 and 220 may include different materials. For example, the first and second insulating material layers 210 and 220 may include silicon oxide, silicon nitride, or the like, but are not limited thereto. For example, the first insulating material layer 210 may include silicon oxide and may not include silicon nitride, and the second insulating material layer 220 may include silicon nitride and may not include silicon oxide; example embodiments are not limited thereto. The first and second insulating material layers 210 and 220 may be formed with an atomic layer deposition (ALD) process, such as with an in-situ ALD process, although example embodiments are not limited thereto.

Referring to FIG. 13B, channel holes 120 are formed through the first and second insulating material layers 210 and 220. The channel holes 120 may extend in the direction perpendicular to the surface of the substrate 101. The channel holes 120 may have a circular cross-sectional shape. An upper surface of the substrate 101 may be exposed through the channel holes 120. The channel holes 120 may be formed with an etching process such as with an anisotropic etching process, including a dry etching process; example embodiments are not limited thereto.

Referring to FIG. 13C, a barrier dielectric layer 121, a charge trap layer 122 including an insertion layer 170 therein, a tunneling dielectric layer 123, a channel layer 124, and a filling insulating layer 125 are sequentially formed on an inner wall of each of the channel holes 120. An ALD process may be used to form each of the layers on the inner wall of each of the channel holes 120, but example embodiments are not limited thereto.

The barrier dielectric layer 121 may be formed on the inner wall of each of the channel holes 120, coming into contact with the first and second insulating material layers 210 and 220. The barrier dielectric layer 121 may include, for example, silicon oxide or a metal oxide, but is not limited thereto.

The charge trap layer 122 including the insertion layer 170 therein may be formed on the barrier dielectric layer 121. The charge trap layer 122 may include a first charge trap layer 122a between the barrier dielectric layer 121 and the insertion layer 170, and a second charge trap layer 122b between the insertion layer 170 and the tunneling dielectric layer 123. The charge trap layer 122 including the insertion layer 170 therein may be formed by sequentially depositing the first charge trap layer 122a, the insertion layer 170, and the second charge trap layer 122b on the barrier dielectric layer 121.

The charge trap layer 122 may include an amorphous high-k oxide. For example, the charge trap layer 122 may include one or more of AlO, HfO, TaO, ZrO, LaO, GaO, YO, BaO, ScO, WO, TiO, or a ternary oxide including a combination of the listed elements. For instance, the charge trap layer 122 may include an amorphous ternary oxide represented by MAlO (where M is Hf, Ta, Zr, La, Ga, Y, Ba, Sc, W, or Ti, Al is aluminum, and O is oxygen). Here, MalO refers to MO+AlO formed by alternately depositing MO and AlO layers. For example, HfAlO refers to HfO+AlO formed by alternately depositing HfO and AlO layers. The ratio of a content of M to a content of (M+Al) in the charge trap layer 122 may range from about 0.2 to less than about 1.0. For instance, the ratio of the content of M to the content of (M+Al) may range from about 0.5 to less than about 1.0.

The insertion layer 170 may include a material with a greater bandgap than the material of the charge trap layer 122. The insertion layer 170 may include, for example, at least one selected from SiO, SiN, AlN, and BN. However, the listed materials are merely examples. As described above, the insertion layer 170 may prevent or reduce the amorphous high-k oxide included in the charge trap layer 122 from crystallizing during a subsequent heat treatment process.

As shown in FIG. 4, the thickness (t1−t2) of the charge trap layer 122 may be from about 50 Å to about 80 Å. For instance, the thickness (t1−t2) of the charge trap layer 122 may be from about 60 Å to about 70 Å. The thickness t2 of the insertion layer 170 may be from about 2 Å to about 15 Å. For instance, the thickness t2 of the insertion layer 170 may be from about 4 Å to about 10 Å.

The tunneling dielectric layer 123 may be formed on the charge trap layer 122 including the insertion layer 170 therein. The tunneling dielectric layer 123, through which charge tunneling occurs, may include, for example, silicon oxide or a metal oxide, but is not limited thereto.

The channel layer 124 may be formed on the tunneling dielectric layer 123. The channel layer 124 may include a semiconductor material. For example, the channel layer 124 may include one or more of Si, Ge, SiGe, a Group III-V semiconductor, or the like. In addition, the channel layer 124 may include an oxide semiconductor, a nitride semiconductor, an oxynitride semiconductor, a two-dimensional semiconductor material, QDs, or an organic semiconductor. For instance, the oxide semiconductor may include InGaZnO, the two-dimensional semiconductor material may include a TMD or graphene, and the QDs may include colloidal QDs or nanocrystal structures. However, the listed materials are merely examples, and embodiments are not limited thereto.

The filling insulating layer 125 may be formed on the channel layer 124 to fill the channel hole 120. In some example embodiments, the filling insulating layer 125 may be formed simultaneously with gate electrodes 131 (described later). The filling insulating layer 125 may include, for example, silicon oxide, air, or the like, but is not limited thereto.

Referring to FIG. 13D, an opening 230 is formed through the first and second insulating material layers 210 and 220, and the second insulating material layers 220 are removed through the opening 230. The opening 230 may be formed with an etching process such as an isotropic etching process including a wet etchant; however, example embodiments are not limited thereto. As a result, the barrier dielectric layer 121 may be exposed.

Referring to FIG. 13E, gate electrodes 131 may be formed in regions from which the second insulating material layers 220 were removed. In addition, the filling insulating layer 125 may be formed simultaneously with the gate electrodes 131. The remaining first insulating material layers 210 may serve as interlayer insulating layers 132. Thereafter, a heat treatment process and/or another annealing process may be performed on a structure shown in FIG. 13E. The annealing process may be or may include a fast thermal annealing process and/or a laser annealing process and/or a thermal furnace annealing process; example embodiments are not limited thereto. As described above, even though the heat treatment process is performed, the high-k oxide including in the charge trap layer 122 may not crystallize but remain in an amorphous state owing to the insertion layer 170 provided inside the charge trap layer 122.

Referring to FIG. 13F, a common source region 110 is formed in an upper portion of the substrate 101 that is exposed through the opening 230. For example, the common source region 110 may be formed by doping, e.g., by implanting, the exposed upper portion of the substrate 101 with an n-type dopant such as phosphorus (P). Referring to FIG. 13G, drains 140 are formed on the channel layers 124, and a bit line 150 is formed on the drains 140.

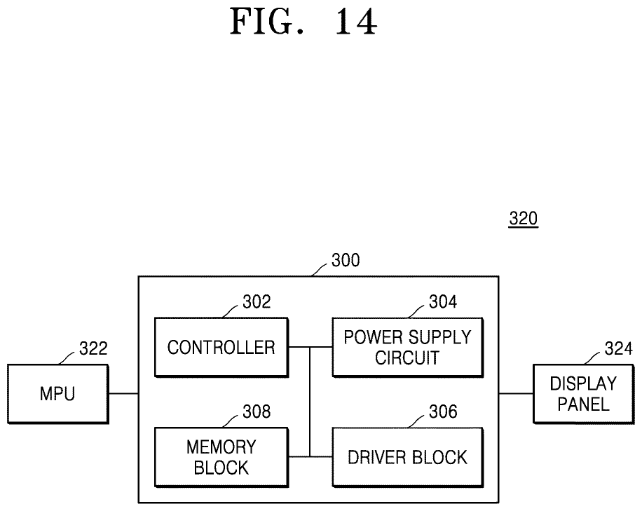

FIG. 14 is a block diagram schematically illustrating a display driver integrated circuit (display driver IC or DDI) 300 and a display apparatus 320 including the DDI 300, according to some example embodiments.

Referring to FIG. 14, the DDI 300 may include a controller 302, a power supply circuit 304, a driver block 306, and a memory block 308. The controller 302 receives and decodes instructions from a main processing unit (MPU) 322 and controls each block of the DDI 300 to implement operations according to the instructions. The power supply circuit 304 generates drive voltage in response to control of the controller 302. The driver block 306 drives a display panel 324 using the drive voltage that is generated by the power supply circuit 304 in response to the control of the controller 302.

The display panel 324 may include, for example, one or more of a liquid crystal display (LCD) panel, an organic light-emitting device (OLED) display panel, or a plasma display panel (PDP). The memory block 308 may temporarily store instructions input to the controller 302 or control signals output from the controller 302, or may store necessary data. The memory block 308 may include memory such as one or more of random access memory (RAM) or read only memory (ROM). For example, the memory block 308 may include the vertical NAND flash memory device 100 described in the above example embodiments.

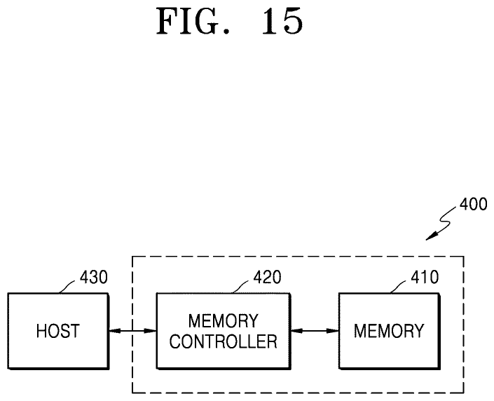

FIG. 15 is a block diagram illustrating an electronic apparatus 400 according to some example embodiments.

Referring to FIG. 15, the electronic apparatus 400 includes memory 410 and a memory controller 420. The memory controller 420 may control the memory 410 to read data from the memory 410 or write data to the memory 410 in response to requests from a host 430. The memory 410 may include the vertical NAND flash memory device 100 described in the above embodiments.

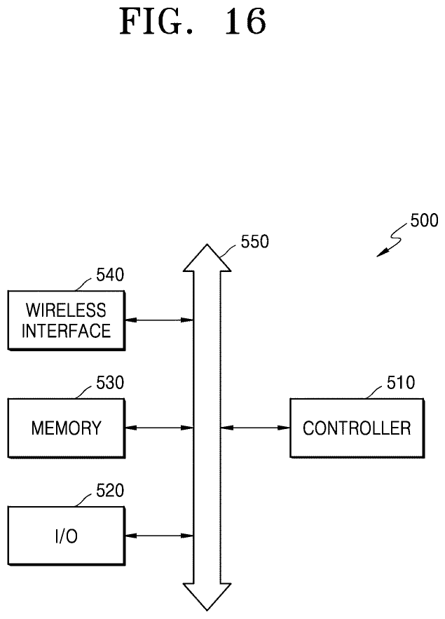

FIG. 16 is a block diagram illustrating an electronic apparatus 500 according to some example embodiments.

Referring to FIG. 16, the electronic apparatus 500 may form a wireless communication device or a device capable of transmitting and/or receiving information in a wireless environment. The electronic apparatus 500 includes a controller 510, an input/output (I/O) device 520, memory 530, and a wireless interface 540 that are connected to each other via a bus 550.

The controller 510 may include at least one selected from a microprocessor, a digital signal processor, and a similar processing device. The I/O device 520 may include at least one selected from a keypad, a keyboard, and a display. The memory 530 may store instructions executed by the controller 510. For example, the memory 530 may store user data. The electronic apparatus 500 may use the wireless interface 540 to transmit/receive data over a wireless communication network. The wireless interface 540 may include an antenna and/or a wireless transceiver. In some embodiments, the electronic apparatus 500 may utilize third-generation communication systems, for example, communication interface protocols of third-generation communication systems such as one or more of code division multiple access (CDMA), global system for mobile communications (GSM), North American digital cellular (NADC), extended time division multiple access (E-TDMA), and/or wide band code division multiple access (WCDMA). The memory 530 of the electronic apparatus 500 may include the vertical NAND flash memory device 100 described in the above embodiments.

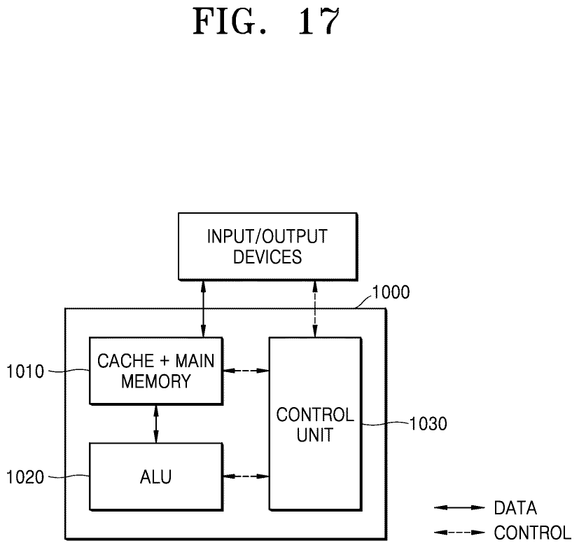

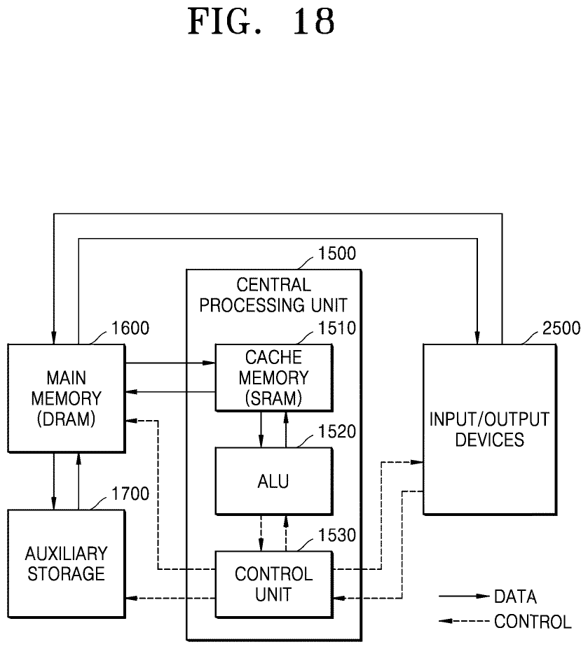

FIGS. 17 and 18 are conceptual views schematically illustrating device architectures applicable to an electronic apparatus according to some example embodiments.

Referring to FIG. 17, an electronic device architecture 1000 may include a memory unit 1010 and a control unit 1030. The electronic device architecture 1000 may further include an arithmetic logic unit (ALU) 1020. The memory unit 1010, the ALU 1020, and the control unit 1030 may be electrically connected to each other. For example, the electronic device architecture 1000 may be implemented as a single chip including the memory unit 1010, the ALU 1020, and the control unit 1030. For example, the memory unit 1010, the ALU 1020, and the control unit 1030 may be interconnected on-chip to enable direct communication. The memory unit 1010, the ALU 1020, and the control unit 1030 may be monolithically integrated on a single substrate to form a single chip. Input/output devices may be connected to the electronic device architecture (chip) 1000. The memory unit 1010 may include main memory and cache memory. The electronic device architecture (chip) 1000 may serve as an on-chip memory processing unit. Each of the memory unit 1010, the ALU 1020, and/or the control unit 1030 may independently include the vertical NAND flash memory device 100 described in the above embodiments.

Referring to FIG. 18, cache memory 1510, an ALU 1520, and a control unit 1530 may form a central processing unit (CPU) 1500, and the cache memory 1510 may include static random access memory (SRAM). In addition to the CPU 1500, main memory 1600 and auxiliary storage 1700 may be provided, and an input/output device 2500 may be provided. For example, the main memory 1600 may include dynamic random access memory (DRAM) and the vertical NAND flash memory device 100 described in the above embodiments.

In some cases, an electronic device architecture may be implemented as a single chip on which computing unit devices and memory unit devices are adjacent to each other without distinguishing between sub-units.

In the vertical NAND flash memory device 100 described in the above embodiments, the insertion layer 170 capable of preventing or reducing crystallization is added inside the charge trap layer 122, thereby maintaining the amorphous high-k oxide of the charge trap layer 122 in an amorphous state even at high temperatures and improving thermal stability. The amorphous high-k oxide of the charge trap layer 122 has higher permittivity than silicon nitride (SiN), enabling a reduction in operating voltage. Alternatively or additionally, the large trap energy E_{T} and high trap density N_{T} of the amorphous high-k oxide may improve charge retention characteristics and increase a memory window. Alternatively or additionally, charge migration may be additionally suppressed using a great bandgap of the insertion layer 170 provided inside the charge trap layer 122, further improving charge retention characteristics. While the vertical NAND flash memory device 100 and the electronic apparatuses including the vertical NAND flash memory device 100 have been described with reference to the accompanying drawings in which some example embodiments are shown, the embodiments are merely examples, and it will be understood by those of ordinary skill in the art that various modifications and equivalent alternative embodiments may be made from the embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A vertical NAND flash memory device comprising:
a plurality of cell strings each extending in a direction perpendicular to a substrate,
wherein each of the plurality of cell strings comprises:
a channel layer;
a charge trap layer on the channel layer and comprising an amorphous oxide;
at least one insertion layer inside the charge trap layer; and
a plurality of gate electrodes on the charge trap layer.

2. The vertical NAND flash memory device of claim 1, wherein the charge trap layer comprises at least one of AlO, HfO, TaO, ZrO, LaO, GaO, YO, BaO, ScO, WO, TiO, or a ternary oxide comprising a combination of the listed metallic elements.

3. The vertical NAND flash memory device of claim 2, wherein the charge trap layer comprises a ternary oxide represented by MAlO where M is Hf, Ta, Zr, La, Ga, Y, Ba, Sc, W, or Ti, Al is aluminum, and O is oxygen.

4. The vertical NAND flash memory device of claim 3, wherein a ratio of a content of M to a content of (M+Al) in the charge trap layer is 0.2 or more.

5. The vertical NAND flash memory device of claim 4, wherein the ratio of the content of M to the content of (M+Al) in the charge trap layer is 0.5 or more.

6. The vertical NAND flash memory device of claim 1, wherein the charge trap layer has a thickness of 50 Å to 80 Å.

7. The vertical NAND flash memory device of claim 1, wherein the at least one insertion layer comprises at least one selected from SiO, SiN, AlN, and BN.

8. The vertical NAND flash memory device of claim 1, wherein the at least one insertion layer has a thickness of 2 Å to 15 Å.

9. The vertical NAND flash memory device of claim 8, wherein the at least one insertion layer has a thickness of 4 Å to 10 Å.

10. The vertical NAND flash memory device of claim 1, further comprising:
a tunneling dielectric layer between the channel layer and the charge trap layer; and
a barrier dielectric layer between the charge trap layer and the plurality of gate electrodes.

11. The vertical NAND flash memory device of claim 1, wherein a channel hole extends through the plurality of gate electrodes in the direction perpendicular to the substrate, and the charge trap layer, the at least one insertion layer, and the channel layer are stacked on an inner wall of the channel hole.

12. The vertical NAND flash memory device of claim 11, wherein the plurality of gate electrodes are apart from each other in the direction perpendicular to the substrate, and each of the plurality of gate electrodes surrounds the charge trap layer.

13. An electronic apparatus comprising the vertical NAND flash memory device of claim 1.

14. A method of fabricating a vertical NAND flash memory device, the method comprising:
alternately stacking a plurality of gate electrodes and a plurality of interlayer insulating layers on a substrate;
forming a channel hole through the plurality of gate electrodes and the plurality of interlayer insulating layers;
forming a charge trap layer comprising an amorphous oxide on an inner wall of the channel hole;
forming an insertion layer inside the charge trap layer;
forming a channel layer on the charge trap layer; and
heat treating the charge trap layer,
wherein the insertion layer is configured to reduce a likelihood of crystallization of a ternary oxide included in the charge trap layer during the heat treating of the charge trap layer.

15. The method of claim 14, wherein the forming of the charge trap layer and the forming of the insertion layer comprise:
forming a first charge trap layer on the inner wall of the channel hole;
forming the insertion layer on the first charge trap layer; and
forming a second charge trap layer on the insertion layer.

16. The method of claim 14, wherein the charge trap layer comprises a ternary oxide represented by MAlO where M is Hf, Ta, Zr, La, Ga, Y, Ba, Sc, W, or Ti, Al is aluminum, and O is oxygen.

17. The method of claim 16, wherein a ratio of a content of M to a content of (M+Al) in the charge trap layer is 0.2 or more.

18. The method of claim 14, wherein the charge trap layer has a thickness of 50 Å to 80 Å.

19. The method of claim 14, wherein the insertion layer comprises at least one selected from SiO, SiN, AlN, and BN.

20. The method of claim 14, wherein the insertion layer has a thickness of 2 Å to 15 Å.
